(19) United States
(12) Patent Application Publication
(10) Pub. No.: US 2026/0339536 A1
(43) Pub. Date: Oct. 29, 2026

(54) DISK ARBITRATION AREA DETECTION METHOD AND APPARATUS, DEVICE, AND NONVOLATILE READABLE STORAGE MEDIUM

(71) Applicant: SUZHOU METABRAIN INTELLIGENT TECHNOLOGY CO., LTD., Suzhou, Jiangsu (CN)

(72) Inventors: Chenxi LIU, Suzhou, Jiangsu (CN); Zhongke YUAN, Suzhou, Jiangsu (CN); Jian WANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/997,359

(22) PCT Filed: Aug. 30, 2023
(86) PCT No.: PCT/CN2023/115982

§ 371 Date: Jan. 21, 2025

(30) Foreign Application Priority Data
Oct. 18, 2022 (CN) 202211269936.5

(51) Int. Cl. G06F 3/06

(52) U.S. Cl. CPC G06F 3/0644; G06F 3/061; G06F 3/0689

(57) ABSTRACT

Provided are a method, apparatus and device of detecting a quorum area in a disk, and a nonvolatile readable storage medium. The method includes: traversing each disk in a multi-control memory system, and if a target disk is currently traversed, determining, based on a preset load balance strategy, a target node for detecting the target disk (S101); detecting, by the target node, a response of a quorum area in the target disk to a verify IO request (S102); and if the response is an IO error message and the target disk is not a system quorum disk, adding, for the target disk, flag information of a quorum area fault (S103).

### CROSS-REFERENCE TO RELATED APPLICATIONS

The present application is a National Stage Application of PCT International Application No.: PCT/CN2023/115982 filed on Aug. 30, 2023, which claims priority to Chinese Patent Application 202211269936.5, filed in the China National Intellectual Property Administration on Oct. 18, 2022, the disclosure of which is incorporated herein by reference in its entirety.

### TECHNICAL FIELD

The present application relates to technical field of computers, and in particular to a method, apparatus and device of detecting a quorum area in a disk and a nonvolatile readable storage medium.

### BACKGROUND

At present, a quorum disk needs to be set in a memory system to record quorum information. Based on the quorum information, it is convenient to determine a main control node in the memory system, or split the memory system into a plurality of memory systems. Currently, member disks of redundant arrays of independent disks (RAID) in the memory system can be detected, so as to determine, according to a detected disk health condition, which disks may be selected as quorum disks. When the RAID member disks are detected, the system needs to bear not only input output (IO) services but also detection tasks, so the overall load of the system may be relatively large, and the overall performance of the system may be reduced.

How to balance the pressures of the disk detection tasks and the IO services on the memory system is a problem that needs to be solved by those skilled in the art.

### SUMMARY

In view of this, objectives of embodiments of the present application are to provide a method, apparatus and device of detecting a quorum area in a disk, and a nonvolatile readable storage medium, so as to balance pressures of disk detection tasks and IO services on a memory system. A detailed solution thereof is as follows:

In a first aspect, an embodiment of the present application provides a method of detecting a quorum area in a disk, including:
traversing each disk in a multi-control memory system, and if a target disk is currently traversed, determining, based on a preset load balance strategy, a target node for detecting the target disk, wherein the target node is any node in the multi-control memory system;
detecting, by the target node, a response of a quorum area in the target disk to a verify IO request; and
if the response is an IO error message and the target disk is not a system quorum disk, adding, for the target disk, flag information of a quorum area fault.

Optionally, the determining, based on a preset load balance strategy, a target node for detecting the target disk includes:
acquiring, from the preset load balance strategy, a correspondence between each node in the multi-control memory system and a disk that is needed to be detected by the each node; and
determining, according to the correspondence, the target node for detecting the target disk.

Optionally, a process of constructing the correspondence includes:
allocating all disks in the multi-control memory system in a balanced manner to each of the nodes in the multi-control memory system, to obtain an allocation result; and
establishing the correspondence according to the allocation result.

Optionally, the detecting, by the target node, a response of a quorum area in the target disk to a verify IO request includes:
reading, by the target node, data stored in any section of contiguous addresses in the quorum area; and
if reading the data fails, determining that the response of the quorum area to the verify IO request is the IO error message.

Optionally, before the determining that the response of the quorum area to the verify IO request is the IO error message, the method further includes:
executing an operation of repairing current contiguous addresses, and if the operation of repairing the contiguous addresses fails, executing the step of determining that the response of the quorum area to the verify IO request is the IO error message.

Optionally, the executing an operation of repairing current contiguous addresses includes:
writing data generated randomly into the current contiguous addresses;
reading data generated randomly from the current contiguous addresses; and
if the read data is consistent with the written data, determining that the operation of repairing the current contiguous addresses is successful; otherwise, determining that the operation of repairing the current contiguous addresses fails.

Optionally, the method further includes:
if successful reading the data or the operation of repairing the current contiguous addresses is successful, when a last address of the current contiguous addresses is not an end address of the quorum area, reading, by the target node, data stored in a next section of contiguous addresses adjacent to the current contiguous addresses, and judging whether reading the data stored in the next section of contiguous addresses is successful or not.

Optionally, the method further includes:
if an offline message of the target disk is acquired during reading the data or the last address of the current contiguous address is the end addresses of the quorum area, waiting for a next detection time point, to traverse a next disk when the next detection time point is reached.

Optionally, the method further includes:
if the response is the IO error message and the target disk is the system quorum disk, generating a fault prompt message of the system quorum disk.

Optionally, after the generating a fault prompt message of the system quorum disk, the method further includes:
collecting the flag information of each disk in the multi-control memory system; and
reselecting the system quorum disk based on the flag information of the each disk.

Optionally, the reselecting the system quorum disk based on the flag information of the each disk includes:
taking one or more disks without the flag information as one or more candidate disks, and selecting, based on a quorum disk selection strategy, the system quorum disk from the one or more candidate disks.

Optionally, the detecting, by the target node, a response of a quorum area in the target disk to a verify IO request includes:
sending, by the target node, a reading request and/or a writing request to the quorum area;
acquiring a processing result of the quorum area for the reading request and/or the writing request; and
taking the processing result of the quorum area for the reading request and/or the writing request as the response of the quorum area to the verify IO request.

Optionally, in a case where the target disk is selected as the system quorum disk, the quorum area in the target disk is configured to store quorum data; and in a case where the target disk is not selected as the system quorum disk, the quorum area in the target disk does not store any data.

Optionally, the quorum area is located at a tail of a memory space of the target disk.

Optionally, the taking the processing result of the quorum area for the reading request and/or the writing request as the response of the quorum area to the verify IO request includes:
in a case where the processing result of the quorum area for the reading request is that a response to reading IO is defective or the processing result of the quorum area for the writing request is that a response to writing IO is defective, determining that the response of the quorum area to the verify IO request is the IO error message.

Optionally, the traversing each disk in a multi-control memory system includes:
according to a setting of a timer, traversing, based on a disk number, all managed disks in the multi-control memory system.

Optionally, the setting of the timer is configured to indicate an interval duration of detection tasks of a same node for different disks.

In a second aspect, an embodiment of the present application provides an apparatus of detecting a quorum area in a disk, including:
a traversing module, configured to traverse each disk in a multi-control memory system, and if a target disk is currently traversed, determine, based on a preset load balance strategy, a target node for detecting the target disk, wherein the target node is any node in the multi-control memory system;
a detection module, configured to detect, by the target node, a response of a quorum area in the target disk to a verify IO request; and
a flagging module, configured to, if the response is an IO error message and the target disk is not a system quorum disk, add, for the target disk, flag information of a quorum area fault.

Optionally, the traversing module is configured to:
acquire, from the preset load balance strategy, a correspondence between each node in the multi-control memory system and a disk that is needed to be detected by the each node; and determine, according to the correspondence, the target node for detecting the target disk.

Optionally, a process of constructing the correspondence includes:
allocate all disks in the multi-control memory system in a balanced manner to each of the nodes in the multi-control memory system, to obtain an allocation result; and establish the correspondence according to the allocation result.

Optionally, the detection module includes:
a reading IO detection unit, configured to read, by the target node, data stored in any section of contiguous address in the quorum area; and if reading the data fails, determine that the response of the quorum area to the verify IO request is the IO error message.

Optionally, the detection module further includes:
a repair unit, configured to execute an operation of repairing current contiguous addresses before it is determined that the response of the quorum area to the verify IO request is the IO error message, and if the operation of repairing the current contiguous addresses fails, execute the step of determining that the response of the quorum area to the verify IO request is the IO error message.

Optionally, the repair unit is configured to:
write data generated randomly into the current contiguous addresses; read data generated randomly from the current contiguous addresses; and if the read data is consistent with the written data, determine that the operation of repairing the current contiguous addresses is successful; otherwise, determining that the operation of repairing the current contiguous addresses fails.

Optionally, the detection module further includes:
a circulation unit, configured to, if successful reading the data or the operation of repairing the current contiguous address is successful, when a last address of the current contiguous addresses is not an end address of the quorum area, read, by the target node, data stored in a next section of contiguous addresses adjacent to the current contiguous addresses, and reading the data stored in next section of contiguous addresses adjacent to the current contiguous addresses is successful or not.

Optionally, the apparatus further includes:
a timing module, configured to, if an offline message of the target disk is acquired during reading the data or the last address of the current contiguous addresses is the end address of the quorum area, wait for a next detection time point, to traverse a next disk when the next detection time point is reached.

Optionally, the apparatus further includes:
a prompt module, configured to, if the response is the IO error message and the target disk is the system quorum disk, generate a fault prompt message of the system quorum disk.

Optionally, the apparatus further includes:
a quorum disk replacing module, configured to after the fault prompt message of the system quorum disk is generated, collect the flag information of each disk in the multi-control memory system; and reselect, based on the flag information of the each disk, the system quorum disk.

Optionally, the quorum disk replacing module is configured to:
take one or more disks without the flag information as one or more candidate disks, and select, based on a quorum disk selection strategy, the system quorum disk from the one or more candidate disks.

Optionally, the detection module is configured to:
send, by the target node, a reading request and/or a writing request to the quorum area;
acquire a processing result of the quorum area for the reading request and/or the writing request; and
take the processing result of the quorum area for the reading request and/or the writing request as the response of the quorum area to the verify IO request.

In a third aspect, an embodiment of the present application provides an electronic device, including:
a memory, configured to store a computer program; and
a processor, configured to execute the computer program, so as to implement the method of detecting a quorum area in a disk disclosed previously.

In a fourth aspect, an embodiment of the present application provides a nonvolatile readable storage medium, configured to store a computer program, wherein when the computer program is executed by a processor, the method of detecting a quorum area in a disk disclosed previously is implemented.

It can be seen from the above solution that the embodiment of the present application provides a method of detecting a quorum area in a disk, including: traversing each disk in a multi-control memory system, and if a target disk is currently traversed, determining, based on a preset load balance strategy, a target node for detecting the target disk, wherein the target node is any node in the multi-control memory system; detecting, by the target node, a response of a quorum area in the target disk to a verify IO request; and if the response is an IO error message and the target disk is not a system quorum disk, adding, for the target disk, flag information of a quorum area fault.

As can be seen, the embodiment of the present application detects a health condition of each disk by traversing each disk in a multi-control memory system, and if a target disk is currently traversed, and determines, based on a preset load balance strategy, a target node for detecting the target disk, so that all nodes in the system bear detection tasks of each disk in the system in a balanced manner, not to such an extent as to affect IO services on certain node due to the fact that the node bears relatively many detection tasks. When each disk is detected in practice, a response of a quorum area in the target disk to a verify IO request is detected by the target node determined by the above step; and if the response is an IO error message and the target disk is not a system quorum disk, flag information of a quorum area fault is added for the target disk, and subsequently, quorum disks can be selected for the system according to the flag information. Furthermore, the embodiment of the present application detects each disk in the system, that is to say, each disk in the system has a probability of being selected as a quorum disk, and the selection range is not limited to RAID member disks in the system. Because service load pressures of non-RAID member disks in the memory system are generally small, they are more suitable to be selected as quorum disks. As can be seen, the embodiment of the present application makes all nodes in the system bear detection tasks of each disk in the system in a balanced manner, so that pressures of disk detection tasks and IO services on the memory system can be balanced. In addition, non-RAID member disks with a relatively small load in the system may also be selected as quorum disks, so that a selection strategy of the quorum disks can be optimized.

Accordingly, an apparatus and device of detecting a quorum area in a disk, and a nonvolatile readable storage medium provided by the embodiments of the present application also have the above technical effects.

### BRIEF DESCRIPTION OF THE DRAWINGS

In order to explain the technical solutions in the embodiments of the present application or the prior art more clearly, drawings that need to be used in the description of the embodiments or the prior art will be briefly introduced below. Obviously, the drawings described below are only embodiments of the present application. For those of ordinary skill in the art, other drawings can also be obtained based on the provided drawings without paying any creative labor.

FIG. 1 is a flowchart of a method of detecting a quorum area in a disk disclosed by an embodiment of the present application;

FIG. 2 is a flowchart of another method of detecting a quorum area in a disk disclosed by an embodiment of the present application;

FIG. 3 is a schematic diagram of result processing of verify IO disclosed by an embodiment of the present application;

FIG. 4 is a schematic diagram of result processing of a write verify instruction disclosed by an embodiment of the present application;

FIG. 5 is a schematic diagram of an apparatus of detecting a quorum area in a disk disclosed by an embodiment of the present application; and

FIG. 6 is a schematic diagram of an electronic device disclosed by an embodiment of the present application.

### DETAILED DESCRIPTION OF THE EMBODIMENTS

Clear and intact description on the technical solutions in the embodiments of the present application will be made below in combination with the drawings in the embodiments of the present application. It is obvious that the embodiments described are only a part of embodiments of the present application, and are not all of embodiments thereof. Based on the embodiments of the present application, all other embodiments obtained by those of ordinary skill in the art without paying any creative labor shall fall within the scope of the protection of the embodiments of the present application.

At present, RAID member disks in a memory system can be detected, so as to determine, according to a detected disk health condition, which disks may be selected as quorum disks. When the RAID member disks are detected, the system needs to bear not only IO services but also detection tasks, so the overall load of the system may be relatively large, and the overall performance of the system may be reduced. In view of this, an embodiment of the present application provides a disk quorum area detection solution, which can balance pressures of disk detection tasks and IO services on a memory system, thereby optimizing a selection strategy of quorum disks.

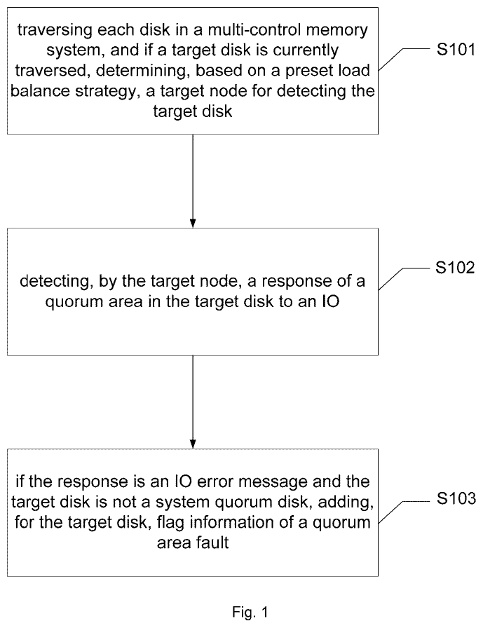

Referring to FIG. 1, an embodiment of the present application discloses a method of detecting a quorum area in a disk, including:

S101, traversing each disk in a multi-control memory system, and if a target disk is currently traversed, determining, based on a preset load balance strategy, a target node for detecting the target disk.

It needs to be noted that, the multi-control memory system includes a plurality of nodes and a plurality of disks, and all the disks are visible to each node. In order to make each node share a detection task of each disk, each disk can be allocated to a corresponding node in a balanced manner, so that each node bears the detection task of each disk in a balanced manner. Assuming that there are 2 nodes and 10 disks in total, each node can bear detection tasks of 5 disks. The target node is any node in the multi-control memory system.

In an implementation, the determining, based on a preset load balance strategy, a target node for detecting the target disk includes: acquiring, from the preset load balance strategy, a correspondence between each node in the multi-control memory system and a disk that is needed to be detected by the each node; and determining, according to the correspondence, the target node for detecting the target disk. A process of constructing the correspondence includes: allocating all disks in the multi-control memory system in a balanced manner to each of the nodes in the multi-control memory system, to obtain an allocation result; and establishing the correspondence according to the allocation result.

S102, detecting, by the target node, a response of a quorum area in the target disk to a verify IO request.

It needs to be noted that, each disk has a partial space serving as a quorum area, and other spaces are configured to store service data. If a certain disk is selected as a system quorum disk, the quorum area in the disk is configured to store quorum data. If a certain disk is not selected as a system quorum disk, the quorum area in the disk does not store any data. The quorum area may be located at a tail of a memory space of each disk, e.g., a size of 512 M is reserved at the tail of each disk to serve as a quorum area. The size of the quorum area can be adjusted according to practical situations.

In this embodiment, the objective of detecting a response of a quorum area to IO is to: detect whether reading and writing functions of the quorum area are defective. For this, the detecting, by the target node, a response of a quorum area in the target disk to a verify IO request includes: sending, by the target node, a reading request and/or a writing request to the quorum area; acquiring a processing result of the quorum area for the reading request and/or the writing request; and taking the processing result of the quorum area for the reading request and/or the writing request as the response of the quorum area to the verify IO request. As can be seen, the response of the quorum area to the verify IO request includes: a response to reading IO and/or a response to writing IO. If the response to reading IO or the response to writing IO is defective, it is considered that the response of the quorum area to the verify IO request has an error, and therefore it is determined that the response is an IO error message.

Since the quorum area is a whole memory space and there may be individual address faults in the whole memory space, in order to detect individual fault addresses in the whole memory space, the quorum area may be detected divisionally. In an implementation, the detecting, by the target node, a response of a quorum area in the target disk to a verify IO request includes: reading, by the target node, data stored in any section of contiguous addresses in the quorum area; and if reading the data fails, determining that the response of the quorum area to the verify IO request is the IO error message. If the data cannot be read from the current contiguous address, it indicates that the current contiguous address is faulty, and therefore it is determined that the response of the quorum area to the verify IO request has an error.

Of course, since a data reading error is accidental, when data cannot be read at a certain contiguous address, an attempt may be made to perform repair operation; after repair fails, it is considered that the response of the quorum area to the verify IO request has an error; and if repair is successful, other addresses in the quorum area continue to be detected. In an implementation, before determining that the response of the quorum area to the verify IO request is the IO error message, the method further includes: executing an operation of repairing current contiguous addresses, and if the operation of repairing the current contiguous addresses fails, executing the step of determining that the response of the quorum area to the verify IO request is the IO error message. The executing an operation of repairing current contiguous addresses includes: writing data generated randomly into the current contiguous addresses; reading data generated randomly from the current contiguous addresses; and if the read data is consistent with the written data, that the operation of repairing the current contiguous addresses is successful; otherwise, determining that the operation of repairing the current contiguous addresses fails.

In an implementation, if successful reading the data or the operation of repairing the current contiguous addresses is successful, when a last address of the current contiguous addresses is not an end address of the quorum area, data stored in a next section of contiguous addresses adjacent to the current contiguous addresses is read by the target node, and processing is performed according to a result whether reading the data stored in the next section of contiguous addresses adjacent to the current contiguous addresses is successful or not.

Of course, disks in the memory system may be offline due to a fault or other reasons, and therefore if an offline message of the target disk is acquired during reading the data or the last address of the current contiguous addresses is the end address of the quorum area, a next detection time point is waited for, to traverse a next disk when the next detection time point is reached. As can be seen, in this embodiment, timed traversing can be performed on all the disks in the system, e.g., after the current disk is detected, the next disk is detected after 3 seconds.

Since quorum information recorded in the system quorum disk is very important, after it is confirmed that the quorum area of the system quorum disk is defective, it is necessary to notify the system in time to replace the system quorum disk. Therefore, in an implementation, if the response is the IO error message and the target disk is the system quorum disk, a fault prompt message of the system quorum disk is generated.

In an implementation, after the generating a fault prompt message of the system quorum disk, the method further includes: collecting the flag information of each disk in the multi-control memory system; and reselecting the system quorum disk based on the flag information of the each disk. The reselecting the system quorum disk based on the flag information of the each disk includes: taking one or more disks without the flag information as one or more candidate disks, and selecting, based on a quorum disk selection strategy, the system quorum disk from the one or more candidate disks, so as to avoid that a quorum area of a newly selected system quorum disk is defective. The quorum disk selection strategy can be made according to the existing relevant art.

The disks in the system may be serial attached scsi (SAS) disks or Non-Volatile Memory express (NVMe) disks. When a disk may be a SAS disk, the target node adopts a scsi bus command to detect a response of a quorum area in the disk to IO; when a disk may be a NVMe disk, the target node adopts a NVMe bus command to detect a response of a quorum area in the disk to IO.

S103, if the response is an IO error message and the target disk is not a system quorum disk, adding, for the target disk, flag information of a quorum area fault.

As can be seen, in this embodiment, a health condition of each disk is detected by traversing each disk in a multi-control memory system, and if a target disk is currently traversed, and determines, based on a preset load balance strategy, a target node for detecting the target disk, so that all nodes in the system bear detection tasks of each disk in the system in a balanced manner, not to such an extent as to affect IO services on certain node due to the fact that the node bears relatively many detection tasks. When each disk is detected in practice, a response of a quorum area in the target disk to a verify IO request is detected by the target node determined by the above step; and if the response is an IO error message and the target disk is not a system quorum disk, flag information of a quorum area fault is added for the target disk, and subsequently, quorum disks can be selected for the system according to the flag information. Furthermore, the embodiment of the present application detects each disk in the system, that is to say, each disk in the system has a probability of being selected as a quorum disk, and the selection range is not limited to RAID member disks in the system. Because service load pressures of non-RAID member disks in the memory system are generally small, they are more suitable to be selected as quorum disks. As can be seen, this embodiment makes all nodes in the system bear detection tasks of each disk in the system in a balanced manner, so that pressures of disk detection tasks and IO services on the memory system can be balanced. In addition, non-RAID member disks with a relatively small load in the system may also be selected as quorum disks, so that a selection strategy of the quorum disks can be optimized.

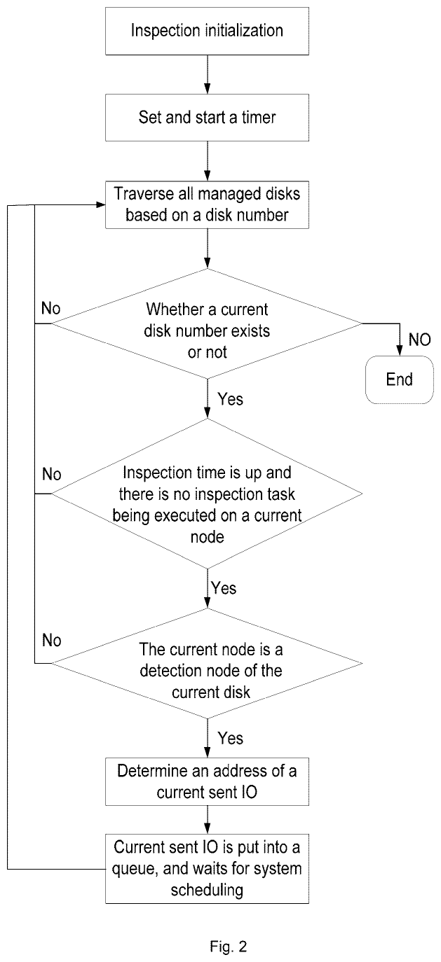

The embodiment of the present application is introduced below by taking a SAS disk and a scsi bus command as an example. For overall logic of the solution of this embodiment, reference may be made to FIG. 2. As shown in FIG. 2, in this embodiment, a disk inspection task and a timer for executing the polling task are set, wherein an execution thread of the inspection task is scrub_scan fibre, and the timer is set in such a manner that detection tasks of the same node for different disks are spaced by 3 seconds; and the detection of different disks by different nodes is also spaced by 3 seconds.

Optionally, according to a setting of the timer, all managed disks in the memory system are traversed based on a disk number, next disk is taken every 3 seconds, the inspection of a quorum area of the disk is started, and an inspection execution thread is scrub_scan fibre. If the disk number exists and the inspection time is up and there is no inspection task being executed on the node (namely, current node) for detecting the current disk, IO sending is performed on a quorum area of the current disk, and the sent IO enters a queue and waits for system scheduling. If the disk number does not exist, or the inspection time is up but the determined node is not used for detecting the current disk, the next disk is detected.

In order to balance the IO load pressures of all nodes in the system, the following strategy is designed to select a detection node for each disk. Assuming that in a double-control system (there are two nodes in a cluster), all managed disks are visible to double-control nodes, the nodes include D0 and D1, and disk numbers drive D of all the managed disks are progressively increased in sequence from D0. Node D0 executes a disk with a drive D being an even number, and node D1 executes a disk with a drive D being an odd number. In this way, detection tasks of each disk are shared in a balanced manner by the two nodes, i.e., D0 and D1, so as to prevent nodes from affecting IO services on the nodes when detecting each disk. Of course, when only one node in the cluster works, the inspection tasks of all the disks are executed at this node. Therefore, for each node, it can be judged whether the current node shall execute the current inspection task of the current disk. In a case where the current node shall execute the current inspection task of the current disk, the next step is entered; and in a case where the current node shall not execute the current inspection task of the current disk, the current execution ends, and operation is performed on the next disk after waiting for 3 seconds.

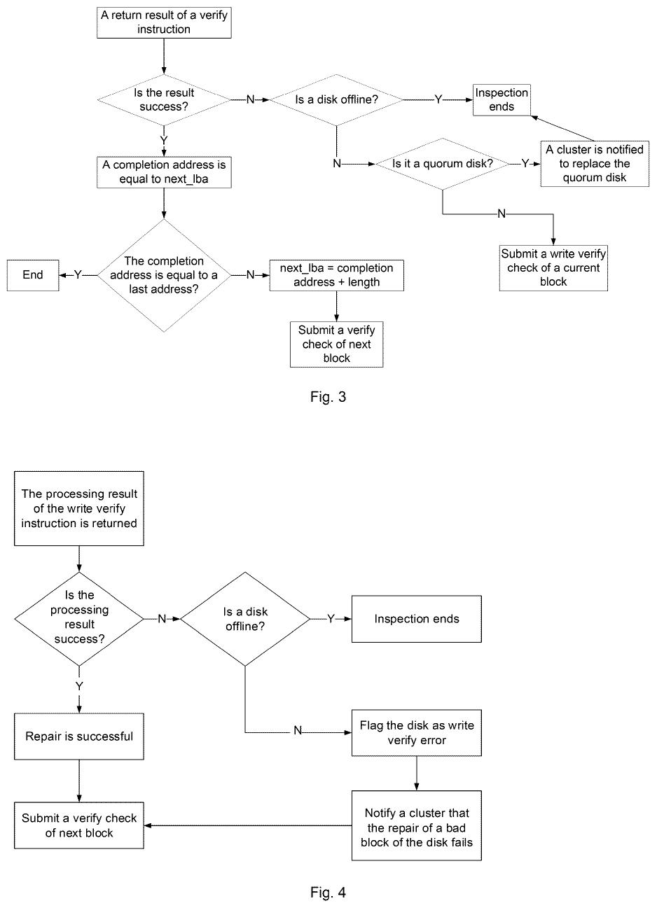

Since in this embodiment, a disk is set to be the SAS disk, whether a target address subjected to IO sending is readable can be detected by a scsi verify instruction. A data length read by every IO sending is 512 bytes, and a quorum area of the disk is 512 M. Optionally, last→lba (last address) of the quorum area of the disk, the data length read by the current IO, and the address next_lba read by next IO can be set. The sent IO in the queue is processed by thread scrub_submit fibre in the node, to determine whether the current IO can read data successfully. For a process of processing IO by scrub_submit fibre, reference may be made to FIG. 3. As shown in FIG. 3, thread scrub_submit fibre takes verify IO from a queue, and submits the verify IO to a designated disk on which the IO is processed, a result (i.e., a verify IO result) is returned, the result is asynchronously scheduled back again to scrub_scan fibre, and scrub_scan fibre confirms the verify IO result. When the returned result is success, it indicates that the status of the current target address of the disk subjected to IO sending is good, and then according to the size relationship between next_lba and last→lba, whether the inspection in the disk quorum area is executed completely is judged. If a current reading completion address is equal to last→lba, it is considered that the inspection in the disk quorum area ends; if the current reading completion address is not equal to last→lba, next→lba=the current reading completion address+length is recalculated, and the IO sending flow is executed again. When the returned result is offline, it indicates that the disk is offline and does not require inspection any more, and then the inspection task of the disk stops immediately. When the returned result is other errors, it indicates that the current target address subjected to IO sending is suspected to be a bad block, and if the disk is a quorum disk of the memory system, the cluster is immediately notified to replace the quorum disk, and the inspection task of the disk is ended; if the disk is not a quorum disk of the system, a write verify instruction is submitted to attempt repair.

Binary data is written by the write verify instruction to the suspected block, and whether read data and written data are consistent is compared, to attempt repair. For a repair process, reference may be made to FIG. 4. As shown in FIG. 4, after the processing result of the write verify instruction is obtained, whether the repair is successful is determined according to the result. When the processing result of the write verify instruction is success, the repair of the bad block is successful, and a verify IO request of an address of the next block continues to be submitted. When the processing result of the write verify instruction is offline, it indicates that the disk is offline and does not require inspection any more, and the inspection task stops immediately. When the processing result of the write verify instruction is other errors, the repair of the bad block fails, the disk is flagged as WRITE VERIFY ERROR, and the cluster is notified at the same time, so that a quorum disk selection mechanism of the memory system uses the result as a selection weight.

As can be seen, this embodiment, according to the scsi verify instruction and the write verify instruction, achieves the detection of the bad blocks in the quorum areas of all the managed disks in the memory system, and the bad blocks in the disk quorum areas can be found in time, thereby ensuring the reliability of data of quorum disks and providing a reliable reference factor for the quorum selection mechanism of the memory system. In this embodiment, for the quorum area of each disk, a verify instruction is sent in a sliding manner by taking an address block as a unit to detect whether there is a bad block, and the repair of the bad block is attempted by sending a write verify instruction, so that the detection of a current disk can be stopped immediately after a certain bad block is detected. The data volume every IO is small, and the entire quorum area of the disk can be prevented from being detected, so that the detection efficiency is relatively high.

An apparatus of detecting a quorum area in a disk provided by an embodiment of the present application is introduced below, and an apparatus of detecting a quorum area in a disk described below and the method of detecting a quorum area in a disk described above can be referred to with each other.

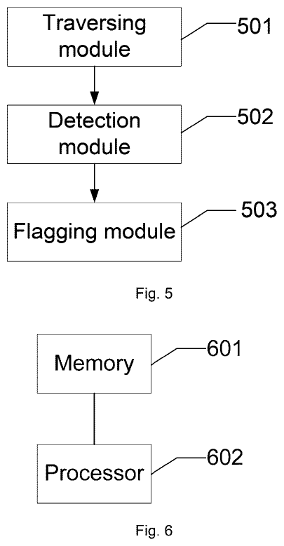

Referring to FIG. 5, an embodiment of the present application discloses an apparatus of detecting a quorum area in a disk, including:
a traversing module 501, configured to traverse each disk in a multi-control memory system, and if a target disk is currently traversed, determine, based on a preset load balance strategy, a target node for detecting the target disk, wherein the target node is any node in the multi-control memory system;
a detection module 502, configured to detect, by the target node, a response of a quorum area in the target disk to a verify IO request; and
a flagging module 503, configured to, if the response is an IO error message and the target disk is not a system quorum disk, add, for the target disk, flag information of a quorum area fault.

In an implementation, the traversing module is configured to:
acquire, from the preset load balance strategy, a correspondence between each node in the multi-control memory system and a disk that is needed to be detected by the each node; and determine, according to the correspondence, the target node for detecting the target disk.

In an implementation, a construction process of the correspondence includes:
allocate all disks in the multi-control memory system in a balanced manner to each of the nodes in the multi-control memory system, to obtain an allocation result; and establish the correspondence according to the allocation result.

In an implementation, the detection module includes:
a reading IO detection unit, configured to read, by the target node, data stored in any section of contiguous addresses in the quorum area; and if reading the data fails, determine that the response of the quorum area to the verify IO request is the IO error message.

In an implementation, the detection module further includes:
a repair unit, configured to execute an operation of repairing current contiguous addresses before it is determined that the response of the quorum area to the verify IO request is the IO error message, and if the operation of repairing the current contiguous addresses fails, execute the step of determining that the response of the quorum area to the verify IO request is the IO error message.

In an implementation, the repair unit is configured to:
write data generated randomly into the current contiguous addresses; read data generated randomly from the current contiguous addresses; and if the read data is consistent with the written data, determine that the operation of repairing the current contiguous addresses is successful; otherwise, determining that the operation of repairing the current contiguous addresses fails.

In an implementation, the detection module further includes:
a circulation unit, configured to, if successful reading the data or the operation of repairing the current contiguous addresses is successful, when a last address of the current contiguous addresses is not an end address of the quorum area, read, by the target node, data stored in a next section of contiguous addresses adjacent to the current contiguous addresses, and judge whether stored in the next section of contiguous addresses is successful or not.

In an implementation, the apparatus further includes:
a timing module, configured to, if an offline message of the target disk is acquired during the reading data or the last address of the current contiguous addresses is the end address of the quorum area, wait for a next detection time point, to traverse a next disk when the next detection time point is reached.

In an implementation, the apparatus further includes:
a prompt module, configured to, if the response is the IO error message and the target disk is the system quorum disk, generate a fault prompt message of the system quorum disk.

In an implementation, the apparatus further includes:
a quorum disk replacing module, configured to after the fault prompt message of the system quorum disk is generated, collect the flag information of each disk in the multi-control memory system; and reselect, based on the flag information of the each disk, the system quorum disk.

In an implementation, the quorum disk replacing module is configured to:
take one or more disks without the flag information as one or more candidate disks, and select, based on a quorum disk selection strategy, the system quorum disk from the one or more candidate disks.

In an implementation, the detection module is configured to:
send, by the target node, a reading request and/or a writing request to the quorum area;
acquire a processing result of the quorum area for the reading request and/or the writing request; and
take the processing result of the quorum area for the reading request and/or the writing request as the response of the quorum area to the verify IO request.

For a more detailed working process of each module and unit in this embodiment, reference may be made to corresponding content disclosed in the foregoing embodiments, and details are not repeatedly described herein.

In view of this, this embodiment provides an apparatus of detecting a quorum area in a disk, which can balance pressures of disk detection tasks and IO services on the memory system, thereby optimizing a selection strategy of quorum disks.

An electronic device provided by an embodiment of the present application is introduced below, and an electronic device described below and the method and apparatus of detecting a quorum area in a disk described above can be referred to with each other.

Referring to FIG. 6, an embodiment of the present application discloses an electronic device, including:
a memory 601, configured to store a computer program; and
a processor 602, configured to execute the computer program, so as to implement the method disclosed by any of the embodiments above.

In this embodiment, when the computer program stored by the memory is executed by the processor, the following steps may be implemented: traversing each disk in a multi-control memory system, and if a target disk is currently traversed, determining, based on a preset load balance strategy, a target node for detecting the target disk, wherein the target node is any node in the multi-control memory system; detecting, by the target node, a response of a quorum area in the target disk to a verify IO request; and if the response is an IO error message and the target disk is not a system quorum disk, adding, for the target disk, flag information of a quorum area fault.

In this embodiment, when the computer program stored by the memory is executed by the processor, the following steps may be implemented: acquiring, from the preset load balance strategy, a correspondence between each node in the multi-control memory system and a disk that is needed to be detected by the each node; and determining, according to the correspondence, the target node for detecting the target disk.

In this embodiment, when the computer program stored by the memory is executed by the processor, the following steps may be implemented: allocating all disks in the multi-control memory system in a balanced manner to the each of nodes in the multi-control memory system, to obtain an allocation result; and establishing the correspondence according to the allocation result.

In this embodiment, when the computer program stored by the memory is executed by the processor, the following steps may be implemented: reading, by the target node, data stored in any section of contiguous addresses in the quorum area; and if reading the data fails, determining that the response of the quorum area to the verify IO request is the IO error message.

In this embodiment, when the computer program stored by the memory is executed by the processor, the following steps may be implemented: executing an operation of repairing current contiguous addresses, and if the operation of repairing the current contiguous addresses fails, executing the step of determining that the response of the quorum area to the verify IO request is the IO error message.

In this embodiment, when the computer program stored by the memory is executed by the processor, the following steps may be implemented: writing data generated randomly into the current contiguous addresses; reading data generated randomly from the current contiguous addresses; and if the read data is consistent with the written data, determining that the operation of repairing the current contiguous addresses is successful; otherwise, determining that the operation of repairing the current contiguous addresses fails.

In this embodiment, when the computer program stored by the memory is executed by the processor, the following steps may be implemented: if successful reading the data or the operation of repairing the current contiguous address is successful, when a last address of the current contiguous addresses is not an end address of the quorum area, reading, by the target node, data stored in a next section of contiguous addresses adjacent to the current contiguous addresses, and judging whether reading the data stored in the next section of contiguous addresses is successful or not.

In this embodiment, when the computer program stored by the memory is executed by the processor, the following steps may be implemented: if an offline message of the target disk is acquired during reading the data or the last address of the current contiguous addresses is the end address of the quorum area, waiting for a next detection time point, to traverse a next disk when the next detection time point is reached.

In this embodiment, when the computer program stored by the memory is executed by the processor, the following steps may be implemented: if the response is the IO error message and the target disk is the system quorum disk, generating a fault prompt message of the system quorum disk.

In this embodiment, when the computer program stored by the memory is executed by the processor, the following steps may be implemented: collecting the flag information of each disk in the multi-control memory system; and reselecting the system quorum disk based on the flag information of the each disk.

In this embodiment, when the computer program stored by the memory is executed by the processor, the following steps may be implemented: taking one or more disks without the flag information as one or more candidate disks, and selecting, based on a quorum disk selection strategy, the system quorum disk from the one or more candidate disks.

In this embodiment, when the computer program stored by the memory is executed by the processor, the following steps may be implemented: sending, by the target node, a reading request and/or a writing request to the quorum area; acquiring a processing result of the quorum area for the reading request and/or the writing request; and taking the processing result of the quorum area for the reading request and/or the writing request as the response of the quorum area to the verify IO request.

Optionally, an embodiment of the present application further provides a server to serve as the electronic device above. The server may include: at least one processor, at least one memory, a power supply, a communication interface, an input/output interface, and a communication bus. The memory is configured to store a computer program, and the computer program is loaded and executed by the processor, so as to implement the relevant steps in the method of detecting a quorum area in a disk disclosed by any of the foregoing embodiments.

In this embodiment, the power supply is configured to provide a working voltage for each hardware device on the server; the communication interface can create a data transmission channel between the server and an external device, and a communication protocol followed thereby is any communication protocol that can be applied to the technical solution of the embodiments of the present application, which is not limited herein; and the input/output interface is configured to acquire external input data or data output to the outside, and an actual interface type thereof can be selected according to actual application requirements, which is not limited herein.

In addition, the memory, as a carrier for resource storage, may be a read-only memory, a random access memory, a magnetic disk, a compact disc, or the like, resources stored thereon include an operating system, a computer program, data, and the like, and a storage manner may be temporary storage or permanent storage.

The operating system is configured to manage and control each hardware device on the server and the computer program, so as to implement calculation and processing of data in the memory by the processor, and it may be a Windows Server, Netware, Unix, Linux, and the like. The computer program may include a computer program which can be used for completing the method of detecting a quorum area in a disk disclosed by any of the foregoing embodiments, and may also include a computer program which can be used for completing other specific works. In addition to data such as a virtual machine, the data can further include data such as developer information of the virtual machine.

Optionally, an embodiment of the present application further provides a terminal to serve as the electronic device above. The terminal may include, but is not limited to, a smart phone, a tablet computer, a notebook computer, a desktop computer, or the like.

Generally, the terminal in this embodiment includes: a processor and a memory.

The processor may include one or more processing cores, such as a 4-core processor and an 8-core processor. The processor may be implemented in at least one hardware form of digital signal processing (DSP), field-programmable gate array (FPGA), and programmable logic array (PLA). The processor may also include a main processor and a coprocessor. The main processor is a processor configured to process data in a wake-up status, and is also referred to as a central processing unit (CPU). The coprocessor is a low-power-consumption processor configured to process data in a standby status. In some embodiments, the processor may be integrated with a graphics processing unit (GPU), and the GPU is configured to be responsible for rendering and drawing of contents required to be displayed by a display screen. In some embodiments, the processor may also include an artificial intelligence (AI) processor, and the AI processor is configured to process computing operations related to machine learning.

The memory may include one or more nonvolatile readable storage media, and the nonvolatile readable storage media may be non-transient. The memory may also include high-speed random access memory, as well as nonvolatile memory, such as one or more disk storage devices, and flash memory storage devices. In this embodiment, the memory is at least configured to store the following computer program, wherein after loaded and executed by the processor, the computer program can implement the relevant steps in the method of detecting a quorum area in a disk executed by a terminal side disclosed by any of the foregoing embodiments. In addition, resources stored by the memory may also include an operating system, data, and the like, and a storage manner may be temporary storage or permanent storage. The operating system may include Windows, Unix, Linux, etc. The data may include, but is not limited to, update information of an application program.

In some embodiments, the terminal may also include: a display screen, an input/output interface, a communication interface, a sensor, a power supply, and a communication bus.

A nonvolatile readable storage medium provided by an embodiment of the present application is introduced below, and a nonvolatile readable storage medium described below and the apparatus and the device of detecting a quorum area in a disk described above can be referred to with each other.

A nonvolatile readable storage medium, is configured to store a computer program, wherein when the computer program is executed by a processor, the method of detecting a quorum area in a disk disclosed by the foregoing embodiments is implemented.

In this embodiment, when the computer program stored by the nonvolatile readable storage medium is executed by the processor, the following steps may be implemented: traversing each disk in a multi-control memory system, and if a target disk is currently traversed, determining, based on a preset load balance strategy, a target node for detecting the target disk, wherein the target node is any node in the multi-control memory system; detecting, by the target node, a response of a quorum area in the target disk to a verify IO request; and if the response is an IO error message and the target disk is not a system quorum disk, adding, for the target disk, flag information of a quorum area fault.

In this embodiment, when the computer program stored by the nonvolatile readable storage medium is executed by the processor, the following steps may be implemented: acquiring, from the preset load balance strategy, a correspondence between each node in the multi-control memory system and a disk that is needed to be detected by the each node; and determining, according to the correspondence, the target node for detecting the target disk.

In this embodiment, when the computer program stored by the nonvolatile readable storage medium is executed by the processor, the following steps may be implemented: allocating all disks in the multi-control memory system in a balanced manner to each of the nodes in the multi-control memory system, to obtain an allocation result; and establishing the correspondence according to the allocation result.

In this embodiment, when the computer program stored by the nonvolatile readable storage medium is executed by the processor, the following steps may be implemented: reading, by the target node, data stored in any section of contiguous addresses in the quorum area; and if reading the data fails, determining that the response of the quorum area to the verify IO request is the IO error message.

In this embodiment, when the computer program stored by the nonvolatile readable storage medium is executed by the processor, the following steps may be implemented: executing an operation of repairing current contiguous addresses, and if the operation of repairing the current contiguous addresses fails, executing the step of determining that the response of the quorum area to the verify IO request is the IO error message.

In this embodiment, when the computer program stored by the nonvolatile readable storage medium is executed by the processor, the following steps may be implemented: writing data generated randomly into the current contiguous addresses; reading data generated randomly from the current contiguous addresses; and if the read data is consistent with the written data, determining that the operation of repairing the current contiguous addresses is successful; otherwise, determining that the operation of repairing the current contiguous addresses fails.

In this embodiment, when the computer program stored by the nonvolatile readable storage medium is executed by the processor, the following steps may be implemented: if successful reading the data or the operation of repairing the current contiguous addresses is successful, when a last address of the current contiguous addresses is not an end address of the quorum area, reading, by the target node, data stored in a next section of contiguous addresses adjacent to the current contiguous addresses, and judging whether reading the data stored in the next section of contiguous addresses is successful or not.

In this embodiment, when the computer program stored by the nonvolatile readable storage medium is executed by the processor, the following steps may be implemented: if an offline message of the target disk is acquired during reading the data or the last address of the current contiguous addresses is the end address of the quorum area, waiting for a next detection time point, to traverse a next disk when the next detection time point is reached.

In this embodiment, when the computer program stored by the nonvolatile readable storage medium is executed by the processor, the following steps may be implemented: if the response is the IO error message and the target disk is the system quorum disk, generating a fault prompt message of the system quorum disk.

In this embodiment, when the computer program stored by the nonvolatile readable storage medium is executed by the processor, the following steps may be implemented: collecting the flag information of each disk in the multi-control memory system; and reselecting the system quorum disk based on the flag information of the each disk.

In this embodiment, when the computer program stored by the nonvolatile readable storage medium is executed by the processor, the following steps may be implemented: taking one or more disks without the flag information as one or more candidate disks, and selecting, based on a quorum disk selection strategy, the system quorum disk from the one or more candidate disks.

In this embodiment, when the computer program stored by the nonvolatile readable storage medium is executed by the processor, the following steps may be implemented: sending, by the target node, a reading request and/or a writing request to the quorum area; acquiring a processing result of the quorum area for the reading request and/or the writing request; and taking the processing result of the quorum area for the reading request and/or the writing request as the response of the quorum area to the verify IO request.

The terms “first”, “second”, “third”, “fourth” and the like (if any) involved in the embodiments of the present application are used for distinguishing similar objects, and are not necessarily used for describing a specific sequence or order. It shall be understood that the data so used may be interchanged where appropriate so that the embodiments described herein may be practiced in an order other than that illustrated or described herein. In addition, the terms “include” and “have”, and any variations thereof, are intended to cover a non-exclusive inclusion, for example, a process, method or device that includes a series of steps or units is not necessarily limited to those steps or units that are expressly listed, but may include other steps or units that are not expressly listed or inherent to such process, method or device.

It needs to be noted that, descriptions related to “first”, “second” and the like in the embodiments of the present application are only for description purposes, and cannot be understood as indicating or implying relative importance thereof or implicitly indicating the number of indicated technical features. Thus, the features defined with “first” and “second” may explicitly or implicitly include at least one of the features. In addition, the technical solutions of the embodiments can be combined with each other, but they must be based on the implementation by those of ordinary skill in the art. When the combination of the technical solutions is contradictory or cannot be implemented, it shall be considered that the combination of the technical solutions does not exist, and does not fall within the scope of protection of the embodiments of the present application.

The embodiments in the present specification are described in a progressive manner. Each embodiment focuses on a difference from other embodiments. For the same or similar parts of the embodiments, reference may be made to each other.

The steps of the method or algorithm described in conjunction with the embodiments disclosed herein may be embodied directly in hardware, in a software module executed by a processor, or in a combination of the two. The software module may be disposed in a random access memory (RAM), a memory, a read-only memory (ROM), an electrically programmable ROM, an electrically erasable programmable ROM, a register, a hard disk, a removable disk, a CD-ROM, or any other form of nonvolatile storage medium known in the art.

The principle and implementations of the embodiments of the present application are described herein by using optional examples, and the description of the foregoing embodiments is merely intended to help understand the method and core idea of the embodiments of the present application. Meanwhile, a person of ordinary skill in the art may make modifications to the alternative implementations and application scopes according to the ideas of the embodiments of the present application. In conclusion, the content of the present specification shall not be understood as a limitation to the embodiments of the present application.

1. A method of detecting a quorum area in a disk, comprising:
traversing each disk in a multi-control memory system, and if a target disk is currently traversed, determining, based on a preset load balance strategy, a target node for detecting the target disk, wherein the target node is any node in the multi-control memory system;
detecting, by the target node, a response of a quorum area in the target disk to a verify IO request; and
if the response is an IO error message and the target disk is not a system quorum disk, adding, for the target disk, flag information of a quorum area fault.

2. The method according to claim 1, wherein the determining, based on a preset load balance strategy, a target node for detecting the target disk comprises:
acquiring, from the preset load balance strategy, a correspondence between each node in the multi-control memory system and a disk that is needed to be detected by the each node; and
determining, according to the correspondence, the target node for detecting the target disk.

3. The method according to claim 2, wherein a process of constructing the correspondence comprises:
allocating all disks in the multi-control memory system in a balanced manner to each of the nodes in the multi-control memory system, to obtain an allocation result; and
establishing the correspondence according to the allocation result.

4. The method according to claim 1, wherein the detecting, by the target node, a response of a quorum area in the target disk to a verify IO request comprises:
reading, by the target node, data stored in any section of contiguous addresses in the quorum area; and
if reading the data fails, determining that the response of the quorum area to the verify IO request is the IO error message.

5. The method according to claim 4, before determining that the response of the quorum area to the verify IO request is the IO error message, further comprising:
executing an operation of repairing current contiguous addresses, and if the operation of repairing the current contiguous addresses fails, executing the step of determining that the response of the quorum area to the verify IO request is the IO error message.

6. The method according to claim 5, wherein the executing an operation of repairing current contiguous addresses comprises:
writing data generated randomly into the current contiguous addresses;
reading data generated randomly from the current contiguous addresses; and
if the read data is consistent with the written data, determining that the operation of repairing the current contiguous addresses is successful; otherwise, determining that the operation of repairing the current contiguous addresses fails.

7. The method according to claim 5, further comprising:
if successful reading the data or the operation of repairing the current contiguous addresses is successful, when a last address of the current contiguous addresses is not an end address of the quorum area, reading, by the target node, data stored in a next section of contiguous addresses adjacent to the current contiguous addresses, and judging whether reading the data stored in the next section of contiguous addresses is successful or not.

8. The method according to claim 7, further comprising:
if an offline message of the target disk is acquired during reading the data or the last address of the current contiguous addresses is the end address of the quorum area, waiting for a next detection time point, to traverse a next disk when the next detection time point is reached.

9. The method according to claim 1, further comprising:
if the response is the IO error message and the target disk is the system quorum disk, generating a fault prompt message of the system quorum disk.

10. The method according to claim 9, after the generating a fault prompt message of the system quorum disk, further comprising:
collecting the flag information of each disk in the multi-control memory system; and
reselecting the system quorum disk based on the flag information of the each disk.

11. The method according to claim 10, wherein the reselecting the system quorum disk based on the flag information of the each disk comprises:
taking one or more disks without the flag information as one or more candidate disks, and selecting, based on a quorum disk selection strategy, the system quorum disk from the one or more candidate disks.

12. The method according to claim 1, wherein the detecting, by the target node, a response of a quorum area in the target disk to a verify IO request comprises:
sending, by the target node, a reading request and/or a writing request to the quorum area;
acquiring a processing result of the quorum area for the reading request and/or the writing request; and
taking the processing result of the quorum area for the reading request and/or the writing request as the response of the quorum area to the verify IO request.

13. The method according to claim 1, wherein in a case where the target disk is selected as the system quorum disk, the quorum area in the target disk is configured to store quorum data; and in a case where the target disk is not selected as the system quorum disk, the quorum area in the target disk does not store any data.

14. The method according to claim 13, wherein the quorum area is located at a tail of a memory space of the target disk.

15. The method according to claim 12, wherein the taking the processing result of the quorum area for the reading request and/or the writing request as the response of the quorum area to the verify IO request comprises:
in a case where the processing result of the quorum area for the reading request is that a response to reading IO is defective or the processing result of the quorum area for the writing request is that a response to writing IO is defective, determining that the response of the quorum area to the verify IO request is the IO error message.

16. The method according to claim 1, wherein the traversing each disk in a multi-control memory system comprises:
according to a setting of a timer, traversing, based on a disk number, all managed disks in the multi-control memory system.

17. The method according to claim 16, wherein the setting of the timer is configured to indicate an interval duration of detection tasks of a same node for different disks.

18. (canceled)

19. An electronic device, comprising:
a memory, configured to store a computer program; and
a processor, configured to execute the computer program, to implement the method according to claim 1.

20. A nonvolatile readable storage medium, configured to store a computer program, wherein when the computer program is executed by a processor, the method according to claim 1 is implemented.

21. The method according to claim 2, further comprising:
if the response is the IO error message and the target disk is the system quorum disk, generating a fault prompt message of the system quorum disk.
